(19) United States
(12) Patent Application Publication
(10) Pub. No.: US 2014/0306876 A1
(43) Pub. Date: Oct. 16, 2014

(54) MOBILE DEVICE AND METHOD OF CHANGING A SHAPE OF A MOBILE DEVICE

(71) Applicant: Samsung Display Co., Ltd., Yongin-City (KR)

(72) Inventors: Hyun-Jae Lee, Yongin-City (KR); Mu-Gyeom Kim, Yongin-City (KR)

(73) Assignee: Samsung Display Co., Ltd., Yongin-City (KR)

(21) Appl. No.: 14/037,233

(22) Filed: Sep. 25, 2013

(30) Foreign Application Priority Data
Apr. 10, 2013 (KR) 10-2013-0039076

(51) Int. Cl. G06F 3/01; H05K 1/02

(52) U.S. Cl. CPC G06F 3/01; H05K 1/0283
USPC 345/156; 361/749

(57) ABSTRACT

A mobile device includes a flexible display panel, a supporting member at a back side of the flexible display panel, the supporting member supporting the flexible display panel, and an electro active polymer partially inserted in the supporting member, a shape of the electro active polymer being changed based on an input value inputted by a user.

### CROSS-REFERENCE TO RELATED APPLICATION

This application claims priority to and the benefit of Korean Patent Application No. 10-2013-0039076, filed on Apr. 10, 2013, the entire disclosure of which is incorporated herein by reference.

### BACKGROUND

1. Field

Example embodiments relate generally to an electronic device. More particularly, embodiments of the invention relate to a mobile device having a changeable shape, and a method of changing a shape of the mobile device.

2. Description of the Related Art

The use of mobile devices such as a laptop computer, a digital camera, a mobile phone, a smart phone, a smart pad, a personal digital assistant (PDA), a portable multimedia player (PMP), an MP3 player, a navigation device, a camcorder, a portable game console, etc. has increased due to developments in the electronics and telecommunications industries.

A flexible display device having a flexible substrate or a film made of a bendable material such as a plastic, etc. has been recently developed. Because the flexible display device has characteristics of thinness, lightness, impact resistance as well as flexibility, the flexible display device may be manufactured to have various shapes. In addition, mobile devices may also have various shapes when the mobile device includes a flexible display device. For this reason, various mobile devices having the flexible display device have been researched and developed.

### SUMMARY

Example embodiments of the present invention provide a mobile device in which the shape can be changed.

Example embodiments of the present invention provide a method of changing the shape of the mobile device.

According to some example embodiments, a mobile device may include a flexible display panel, a supporting member at on a back side of the flexible display panel, the supporting member supporting the flexible display panel, and an electro active polymer partially inserted in the supporting member. A shape of the electro active polymer may be changed based on an input value inputted by a user.

In example embodiments, the mobile device may further include a driving controller configured to control the electro active polymer based on the input value.

In example embodiments, the electro active polymer may be a sheet-type and may include a left electro active polymer pattern and a right electro active polymer pattern that may be independently controlled by the driving controller.

In example embodiments, the driving controller may detect an event of the mobile device, and to control the electro active polymer based on the event.

In example embodiments, the driving controller may include a database that stores a preset input signal corresponding to the event, may search the preset input signal from the database when the event is detected, and to control the electro active polymer based on the searched preset input signal.

In example embodiments, the preset input signal may include at least one of an outer curvature of the mobile device, a changing-pattern of the outer curvature of the mobile device, or a motion pattern of the mobile device that may be inputted through a user application program.

In example embodiments, the input value may include at least one of an outer curvature of the mobile device, a changing-pattern of the outer curvature of the mobile device, or a motion pattern of the mobile device that may be inputted through a user application program.

According to some example embodiments, a mobile device may include a flexible display panel and an electro active polymer at a back side of the flexible display panel. A shape of the electro active polymer may be changed based on an input value inputted by a user.

In example embodiments, the mobile device may further include a driving controller configured to control the electro active polymer based on the input value.

In example embodiments, the electro active polymer may include a plurality of electro active polymer patterns having a shell-shape and may support the display panel according to whether or not voltage is applied.

In example embodiments, the driving controller may detect an event of the mobile device, and to control the electro active polymer based on the event.

In example embodiments, the driving controller may include a database that stores a preset input signal corresponding to the event, may search the preset input signal from the database when the event is detected, and to control the electro active polymer based on the searched preset input signal.

In example embodiments, the preset input signal may include at least one of an outer curvature of the mobile device, a changing-pattern of the outer curvature of the mobile device, or a motion pattern of the mobile device that may be inputted through a user application program.

In example embodiments, the input value may include at least one of an outer curvature of the mobile device, a changing-pattern of the outer curvature of the mobile device, or a motion pattern of the mobile device that may be inputted through a user application program.

According to some example embodiments, a method of changing a shape of a mobile device may include a step of executing a user application program, inputting an input value including at least one of an outer curvature of a mobile device, a changing-pattern of the outer curvature of the mobile device, or a motion pattern of the mobile device, that is inputted through the user application program, transmitting the input value to a driving controller and controlling an electro active polymer based on the input value.

In example embodiments, the method of changing the shape of the mobile device may further include a step of detecting an event of the mobile device, and the driving controller controls the electro active polymer based on the event.

In example embodiments, the driving controller may include a database that stores a preset input signal corresponding to the event, may search the preset input signal from the database when the event is detected, and may control the electro active polymer based on the searched preset input signal.

In example embodiments, the preset input signal may include the at least one of the outer curvature of the mobile device, the changing-pattern of the outer curvature of the mobile device, or a motion pattern of the mobile device that may be inputted through a user application program.

In example embodiments, controlling the electro active polymer may be stopped when one or more of the outer curvature of the mobile device, the changing-pattern of the outer curvature of the mobile device, and the motion pattern of the mobile device are matched to the preset input value.

In example embodiments, the input value may include the at least one of the outer curvature of the mobile device, the changing-pattern of the outer curvature of the mobile device, or the motion pattern of the mobile device that may be inputted through a user application program.

In example embodiments, controlling the electro active polymer may be stopped when one or more the outer curvature of the mobile device, the changing-pattern of the outer curvature of the mobile device, and the motion pattern of the mobile device are matched to the input value.

Therefore, a mobile device according to example embodiments may have an improved or optimized shape structure according to a user, a surrounding circumstance, and an input manner by including an electro active polymer of which a shape is changed based on an input value inputted by the user. As a result, portability and usability of the mobile device may be improved.

### BRIEF DESCRIPTION OF THE DRAWINGS

Illustrative, non-limiting example embodiments will be more clearly understood from the following detailed description taken in conjunction with the accompanying drawings wherein:

FIG. 1 is a cross-sectional view illustrating a mobile device in accordance with example embodiments;

FIG. 2 is a cross-sectional view illustrating a mobile device in accordance with example embodiments;

FIG. 3 is a cross-sectional view illustrating an example of a display panel included in mobile devices of FIGS. 1 and 2;

FIGS. 4A through 4C are diagrams illustrating a changing shape of a mobile device in accordance with example embodiments;

FIGS. 5A and 5B are diagrams illustrating a changing shape of a mobile device in accordance with example embodiments;

FIG. 6 is a flow chart illustrating a method of changing a shape of a mobile device in accordance with example embodiments; and

FIG. 7 is a flow chart illustrating a method of changing a shape of a mobile device in accordance with example embodiments.

### DETAILED DESCRIPTION

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this disclosure will be thorough and complete, and will fully convey the scope of the present inventive concept to those skilled in the art. In the drawings, the sizes and relative sizes of layers and regions may be exaggerated for clarity. Like numerals refer to like elements throughout.

It will be understood that, although the terms first, second, third, etc., may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

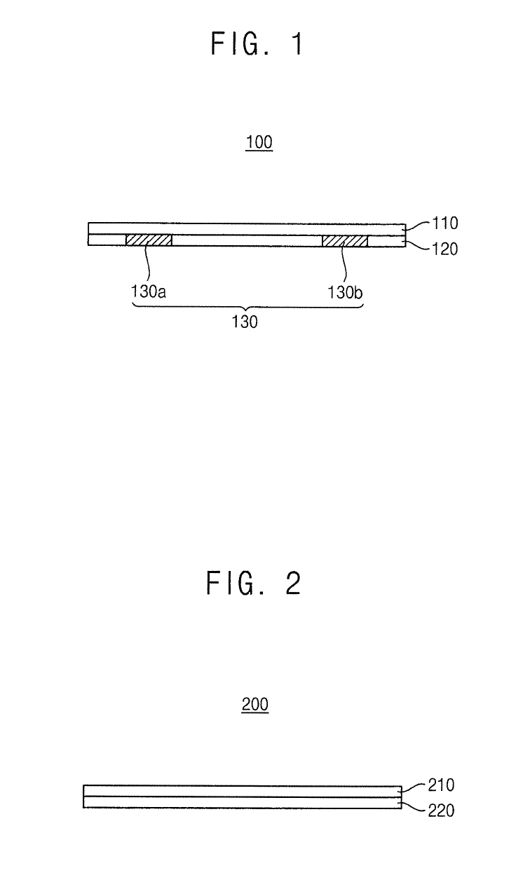

FIG. 1 is a cross-sectional view illustrating a mobile device in accordance with example embodiments.

Referring to FIG. 1, a mobile device 100 includes a display panel 110, a supporting member 120, and an electro active polymer 130.

The display panel 110 may include a flexible display panel. In example embodiments, since the electro active polymer 130 may be partially inserted in the supporting member 120 on a back side of the display panel 110, a shape of the display panel 110 may be partially changed. A changing-shape of the display panel 110 due to the electro active polymer 130 will be described below in detail.

In example embodiments, the display panel 110 may correspond to a display panel of an organic light emitting display (OLED) device. However, the present inventive concept is not limited thereto. For example, the display panel 110 may correspond to a display panel of a liquid crystal display (LCD) device.

In example embodiments, the supporting member 120 may be disposed on the back side of the display panel 110, and may support the display panel 110 so that the supporting member 120 may ensure a uniform flatness of the display panel 110 when different voltages are applied to a left electro active polymer 130a and a right electro active polymer 130b.

For example, the supporting member 120 may be made of plastic and/or metal. However, the present inventive concept is not limited thereto. Alternatively, the supporting member 120 may include other prescribed materials having a predetermined strength.

The electro active polymer 130 may be partially inserted in the supporting member 120, and may change the shape of the display panel 110. In example embodiments, the electro active polymer 130 may include an electro active polymer pattern having a sheet-shape. For example, the electro active polymer pattern may include the left electro active polymer 130a and the right electro active polymer 130b.

In example embodiments, a shape of the electro active polymer 130 may be changed based on an input value inputted by a user. For example, the input value may be inputted through a user application program. Alternatively, the input value may be inputted through an environmental setting program, a bundle program or a bearer or embedded in an operating system (OS), etc. The input value may include at least one of an outer curvature of the mobile device 100, a changing-pattern of the outer curvature of the mobile device 100, or a motion pattern of the mobile device 100. The input value may be adjusted according to a user setting. For example, a user may set the outer curvature of the mobile device 100, the changing-pattern of the outer curvature of the mobile device 100, and/or the motion pattern of the mobile device 100 by operating the user application program or the environment setting program. In addition, a shape of the mobile device 100 may be changed according to the set outer curvature of the mobile device 100, the set changing-pattern of the outer curvature of the mobile device 100, and the set motion pattern of the mobile device 100. Here, the user application program may be built in the mobile device 100. Alternatively, the user application program may be obtained through a wired network and/or a wireless network.

For example, the mobile device 100 may further include a driving controller which controls the electro active polymer 130 based on the input value. Alternatively, the driving controller may include a database that detects an event of the mobile device 100 (e.g., a reception of a call, a reception of a text message, etc.), and that controls the electro active polymer 130 based on the event. The database may store a preset input signal corresponding to the event. In one example embodiment, the preset input signal may be prestored in the database when the mobile device 100 is manufactured. In another example embodiment, the preset input signal may be stored or updated in the database by a user setting. In still another example embodiment, the preset input signal may be adaptively stored or updated in the database by reflecting a user's habit to use the mobile device 100. Accordingly, the driving controller may search the preset input signal from the database when the event is detected, and may control the electro active polymer 130 based on the searched preset input signal. The preset input signal may include at least one of an outer curvature of the mobile device 100, a changing-pattern of the outer curvature of the mobile device 100, or a motion pattern of the mobile device 100. The driving controller may independently control the left electro active polymer pattern 130a and the right electro active polymer pattern 130b.

Therefore, a mobile device 100 according to example embodiments may have an optimized or improved shape structure according to a user, a surrounding circumstance, and an input manner by including an electro active polymer 130 of which a shape is changed based on an input value inputted by the user. As a result, portability and usability of the mobile device 100 may be improved.

According to example embodiments, the mobile device 100 may be an electronic device such as a mobile phone, a smart phone, a laptop computer, a tablet computer, a personal digital assistant (PDA), a portable multimedia player (PMP), a digital camera, a music player, a portable game console, a navigation device, etc.

FIG. 2 is a cross-sectional view illustrating a mobile device in accordance with example embodiments. Since the mobile device 200 of FIG. 2 has a structure that is substantially the same as or substantially similar to the mobile device 100 of FIG. 1 except for the electro active polymer 130, duplicated descriptions will be omitted below.

Referring to FIG. 2, a mobile device 200 may include a display panel 210 and an electro active polymer 220.

The display panel 210 may include a flexible display panel. In example embodiments, since the electro active polymer 220 is disposed on a back side of the display panel 210, a shape of the display panel 210 may be partially changed. A changing-shape of the display panel 210 due to the electro active polymer 220 will be described below in detail.

In example embodiments, the display panel 210 may include a display panel of an OLED device. However, the present inventive concept is not limited thereto. For example, the display panel 210 may include a display panel of an LCD device.

The electro active polymer 220 may be disposed on the back side of the display panel 210. For example, the electro active polymer 220 may include a plurality of electro active polymer patterns having a shell-shape, so that the electro active polymer 220 may support the display panel 210 according to whether a voltage is applied to the electro active polymer 220, and may change the shape of the mobile device 200 based on the input value inputted by the user. Here, the input value may be inputted through a user application program. Alternatively, the input value may be inputted through an environmental setting program, a bundle program or a bearer embedded in an operating system, etc. The input value may include at least one of an outer curvature of the mobile device 200, a changing-pattern of the outer curvature of the mobile device 200, or a motion pattern of the mobile device 200. The input value may be adjusted according to a user setting. For example, a user may set the outer curvature of the mobile device 200, the changing-pattern of the outer curvature of the mobile device 200, and/or the motion pattern of the mobile device 200 by operating the user application program or the environment setting program. In addition, a shape of the mobile device 200 may be changed according to the set outer curvature of the mobile device 200, the set changing-pattern of the outer curvature of the mobile device 200, and/or the set motion pattern of the mobile device 200. For example, the user application program may be built in the mobile device 200. Alternatively, the application may be obtained through a wired network and/or a wireless network.

For example, the mobile device 200 may further include a driving controller which controls the electro active polymer 220 based on the input value. Alternatively, the driving controller may include a database that detects an event of the mobile device 200 (e.g., a reception of a call, a reception of a text message, etc.), and that controls the electro active polymer 220 based on the event. The database may store a preset input signal corresponding to the event. In one example embodiment, the preset input signal may be prestored in the database when the mobile device 200 is manufactured. In another example embodiment, the preset input signal may be stored or updated in the database by a user setting. In still another example embodiment, the preset input signal may be adaptively stored or updated in the database by reflecting a user's habit to use the mobile device 200. Accordingly, the driving controller may search the preset input signal from the database when the event is detected, and may control the electro active polymer 130 based on the searched preset input signal. The preset input signal may include at least one of an outer curvature of the mobile device 200, a changing-pattern of the outer curvature of the mobile device 200, or a motion pattern of the mobile device 200.

Therefore, a mobile device 200 according to example embodiments may have an optimized or improved shape structure according to a user, a surrounding circumstance, and/or an input manner by including an electro active polymer 220 of which a shape is changed based on an input value inputted by the user. As a result, portability and usability of the mobile device 200 may be improved.

According to example embodiments, the mobile device 200 may be an electronic device such as a mobile phone, a smart phone, a laptop computer, a tablet computer, a personal digital assistant, a portable multimedia player, a digital camera, a music player, a portable game console, a navigation device, etc.

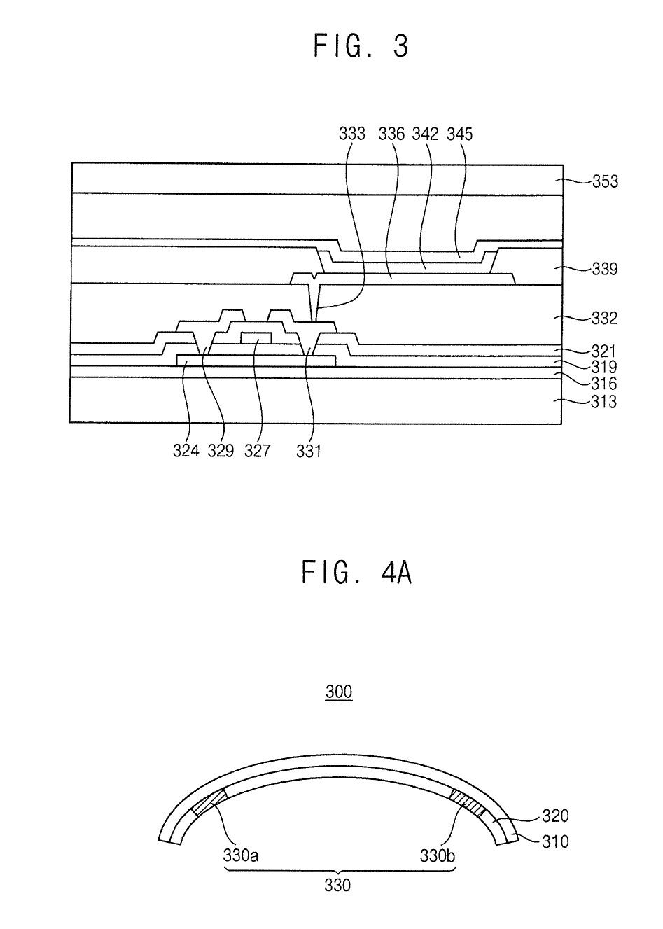

FIG. 3 is a cross-sectional view illustrating an example of a display panel included in mobile devices of FIGS. 1 and 2. The display panel illustrated in FIG. 3 may correspond to the display panel 110 of the mobile device 100 of FIG. 1 and/or the display panel 210 of the mobile device 200 of FIG. 2.

The display panel may include a first substrate 313, a switching device, a first electrode 336, an organic light emitting structure 342, a second electrode 345, a second substrate 353, etc.

A buffer layer 316 may be disposed on the first substrate 313. The first substrate 313 may include a transparent insulation substrate. For example, the first substrate 313 may include a glass substrate, a quartz substrate, a transparent resin substrate, etc. Examples of the transparent resin substrate for the first substrate 313 may include polyimide-based resin, acryl-based resin, polyacrylate-based resin, polycarbonate-based resin, polyether-based resin, sulfonic acid-containing resin, polyethyleneterephthalate-based resin, etc.

In example embodiments, the buffer layer 316 may prevent diffusion of metal atoms and/or impurities from the first substrate 313. Additionally, the buffer layer 316 may adjust heat transfer rate of a successive crystallization process for an active pattern 324, to thereby obtain a substantially uniform active pattern 324. In case that the first substrate 313 may have a relatively irregular surface, the buffer layer 316 may improve flatness of the surface of the first substrate 313. The buffer layer 316 may be formed using a silicon compound. For example, the buffer layer 316 may include silicon oxide (SiOx), silicon nitride (SiNx), silicon oxynitride (SiOxNy), silicon oxycarbide (SiOxCy), silicon carbon nitride (SiCxNy), etc. These may be used alone or in a mixture thereof. The buffer layer 316 may have a single layer structure or a multi layer structure. For example, the buffer layer 316 may have a single layer structure including a silicon oxide film, a silicon nitride film, a silicon oxynitride film, a silicon oxycarbide film, or a silicon carbon nitride film. Alternatively, the buffer layer 316 may have a multi layer structure including at least two of a silicon oxide film, a silicon nitride film, a silicon oxynitride film, a silicon oxycarbide film, a silicon carbon nitride film, etc.

The switching device may be provided on the buffer layer 316. In example embodiments, the switching device may include a thin film transistor (TFT) having the active pattern 324 that may contain silicon (Si). For example, the switching device may include the active pattern 324, a gate insulation layer 319, a gate electrode 327, a source electrode 329, a drain electrode 331, etc. Alternatively, the switching device may include an oxide semiconductor device having an active pattern that may contain semiconductor oxides.

When the switching device includes the TFT, the active pattern may be disposed on the buffer layer 316. The active pattern 324 may have a source region and a drain region both of which are doped with impurities. The active pattern 324 may additionally include a channel region provided between the source region and the drain region.

In example embodiments, a semiconductor layer (not illustrated) may be formed on the buffer layer 316, and then a preliminary active layer (not illustrated) may be formed on the buffer layer 316 by patterning the semiconductor layer. The crystallization process may be executed on the preliminary active layer to form the active pattern 324 on the buffer layer 316. When the semiconductor layer includes amorphous silicon, the active pattern 313 may include polysilicon. The crystallization process for forming the active pattern 313 may include a laser irradiation process, a thermal treatment process, a thermal process utilizing a catalyst, etc.

The gate insulation layer 319 may be disposed on the buffer layer 316 to cover the active pattern 324. The gate insulation layer 319 may include silicon oxide, metal oxide, etc. Examples of metal oxide in the gate insulation layer 319 may include hafnium oxide (HfOx), aluminum oxide (AlOx), zirconium oxide (ZrOx), titanium oxide (TiOx), tantalum oxide (TaOx), etc. These may be used alone or in a combination thereof. In example embodiments, the gate insulation layer 319 may be uniformly formed on the buffer layer 316 along a profile of the active pattern 324. For example, the gate insulation layer 319 may have a substantially small thickness, such that a stepped portion may be generated at a portion of the gate insulation layer 319 adjacent to the active pattern 324. Alternatively, the gate insulation layer 319 may have a relatively large thickness for sufficiently covering the active pattern 324, so that the gate insulation layer 319 may have a substantially level surface.

The gate electrode 327 may be located on the gate insulation layer 319. For example, the gate electrode 327 may be positioned on a portion of the gate insulation layer 319 under which the active pattern 324 is located. In example embodiments, a first conductive layer (not illustrated) may be formed on the gate insulation layer 319, and then the first conductive layer may be partially etched by a photolithography process or an etching process using an additional etching mask. Hence, the gate electrode 327 may be provided on the gate insulation layer 319. The gate electrode 327 may include metal, alloy, conductive metal oxide, a transparent conductive material, etc. For example, the gate electrode 327 may be formed using aluminum (Al), alloy containing aluminum, aluminum nitride (AlNx), silver (Ag), alloy containing silver, tungsten (W), tungsten nitride (WNx), copper (Cu), alloy containing copper, nickel (Ni), alloy containing nickel, chrome (Cr), chrome nitride (CrNx), molybdenum (Mo), alloy containing molybdenum, titanium (Ti), titanium nitride (TiNx), platinum (Pt), tantalum (Ta), tantalum nitride (TaNx), neodymium (Nd), scandium (Sc), strontium ruthenium oxide (SRO), zinc oxide (ZnOx), indium tin oxide (ITO), tin oxide (SnOx), indium oxide (InOx), gallium oxide (GaOx), indium zinc oxide (IZO), etc. These may be used alone or in a combination thereof. In example embodiments, the gate electrode 327 may have a single layer structure or a multi layer structure, which may include a metal film, an alloy film, a metal nitride film, a conductive metal oxide film, and/or a transparent conductive film.

An insulating interlayer 321 may be disposed on the gate insulation layer 319 to cover the gate electrode 327. The insulating interlayer 321 may electrically insulate the source and the drain electrodes 329 and 331 from the gate electrode 327. The insulating interlayer 321 having a substantially uniform thickness may be conformally formed on the gate insulation layer 319 along a profile of the gate electrode 327. Thus, a stepped portion may be generated at a portion of the insulating interlayer 321 adjacent to the gate electrode 327. The insulating interlayer 321 may be formed using a silicon compound. For example, the insulating interlayer 321 may include silicon oxide, silicon nitride, silicon oxynitride, silicon oxycarbide and/or silicon carbon nitride. These may be used alone or in a mixture thereof. In example embodiments, the insulating interlayer 321 may have a single layer structure or a multi layer structure, which may include a silicon oxide film, a silicon nitride film, a silicon oxynitride film, a silicon oxycarbide film, and/or a silicon carbon nitride film.

As illustrated in FIG. 3, the source electrode 329 and the drain electrode 331 may be disposed on the insulating interlayer 321. The source and the drain electrodes 329 and 331 may be separated from each other by a predetermined distance with the gate electrode 327 located at or near the midpoint (e.g., center) therebetween. The source and the drain electrodes 329 and 331 may pass through the insulating interlayer 321, and may contact the source and the drain regions of the active pattern 324, respectively.

In example embodiments, the insulating interlayer 321 may be partially etched to form contact holes exposing the source and the drain regions, respectively. Then, a second conductive layer (not illustrated) may be formed on the insulating interlayer 321 to fill the contact holes. The second conductive layer may be removed until the insulating interlayer 321 is exposed, so that the source and the drain electrodes 329 and 331 may be formed on the source and the drain regions (e.g., contact), respectively. Each of the source and the drain electrodes 329 and 331 may include metal, alloy, metal nitride, conductive metal oxide, a transparent conductive material, etc. For example, the source and the drain electrodes 329 and 331 may be formed using aluminum, alloy containing aluminum, aluminum nitride, silver, alloy containing silver, tungsten, tungsten nitride, copper, alloy containing copper, nickel, alloy containing nickel, chrome, chrome nitride, molybdenum, alloy containing molybdenum, titanium, titanium nitride, platinum, tantalum, tantalum nitride, neodymium, scandium, strontium ruthenium oxide, zinc oxide, indium tin oxide, tin oxide, indium oxide, gallium oxide, indium zinc oxide, etc. These may be used alone or in a combination thereof. In example embodiments, each of the source and the drain electrodes 329 and 331 may have a single layer structure or a multi layer structure, which may include a metal film, an alloy film, a metal nitride film, a conductive metal oxide film, and/or a transparent conductive film.

Through formation of the source and the drain electrodes 329 and 331 on the insulating interlayer 321, the switching device may be provided on the first substrate 313. The switching device may include the TFT that may have the active pattern 324, the gate insulation layer 319, the gate electrode 327, the source electrode 329, and the drain electrode 331.

An insulation layer 332 may be disposed on the insulating interlayer 321 to cover the source and drain electrodes 329 and 331. The insulation layer 332 may have a single layer structure or a multi layer structure including at least two insulation films. In example embodiments, a planarization process may be executed on the insulation layer 332 to enhance the flatness of the insulation layer 332. For example, the insulation layer 332 may have a substantially level surface by a chemical mechanical polishing (CMP) process, an etch-back process, etc. The insulation layer 332 may be formed using an organic material. For example, the insulation layer 332 may include photoresist, acryl-based resin, polyimide-based resin, polyamide-based resin, siloxane-based resin, etc. These may be used alone or in a combination thereof. Alternatively, the insulation layer 332 may include an inorganic material. For example, the insulation layer 332 may be formed using silicon oxide, silicon nitride, silicon oxynitride, silicon oxycarbide, aluminum, magnesium, zinc, hafnium, zirconium, titanium, tantalum, aluminum oxide, titanium oxide, tantalum oxide, magnesium oxide, zinc oxide, hafnium oxide, zirconium oxide, titanium oxide, etc. These may be used alone or in a mixture thereof.

The insulation layer 332 may be partially etched by a photolithography process or an etching process using an additional etching mask such as a hard mask, so that a contact hole 333 may be formed through the insulation layer 332. The contact hole 333 may partially expose the drain electrode 331 of the switching device. In example embodiments, the contact hole 333 may have a sidewall inclined by a predetermined angle relative to the first substrate 313. For example, the contact hole 333 may have an upper width substantially larger than a lower width thereof.

A first electrode 336 may be disposed on the insulation layer 332 to fill the contact hole 333 formed through the insulation layer 332. Thus, the first electrode 336 may make contact with the drain electrode 331 exposed by the contact hole 333. Alternatively, a contact, a plug, or a pad may be formed in the contact hole 333, and then the first electrode 336 may be formed on the contact, the plug, or the pad. For example, the first electrode 336 may be electrically connected to the drain electrode 331 through the contact, the plug, or the pad.

The first electrode 336 may include a reflective material and/or a transparent material in accordance with the emission type of the display device. For example, the first electrode 336 may be formed using aluminum, alloy containing aluminum, aluminum nitride, silver, alloy containing silver, tungsten, tungsten nitride, copper, alloy containing copper, nickel, alloy containing nickel, chrome, chrome nitride, molybdenum, alloy containing molybdenum, titanium, titanium nitride, platinum, tantalum, tantalum nitride, neodymium, scandium, strontium ruthenium oxide, zinc oxide, indium tin oxide, tin oxide, indium oxide, gallium oxide, indium zinc oxide, etc. These may be used alone or in a combination thereof. In example embodiments, the first electrode 336 may have a single layer structure or a multi layer structure, which may include a metal film, an alloy film, a metal nitride film, a conductive metal oxide film, and/or a transparent conductive film.

A pixel defining layer 339 may be disposed on the first electrode 336 and the insulation layer 332. The pixel defining layer 339 may include an organic material or an inorganic material. For example, the pixel defining layer 339 may be formed using photoresist, acryl-based resin, polyacryl-based resin, polyimide-based resin, a silicon compound, etc. In example embodiments, the pixel defining layer 339 may be partially etched to form an opening partially exposing the first electrode 336. The opening of the pixel defining layer 339 may define a luminescent region and a non-luminescent region of the display device. For example, a portion having the opening of the pixel defining layer 339 may be the luminescent region of the display device while another portion around the opening of the pixel defining layer 339 may be the non-luminescent region of the display device.

A light emitting structure 342 may be positioned on the first electrode 336 exposed by the opening of the pixel defining layer 339. The light emitting structure 342 may extend on a sidewall of the opening of the pixel defining layer 339. In example embodiments, the light emitting structure 342 may include an organic light emitting layer (EL), a hole injection layer (HIL), a hole transfer layer (HTL), an electron transfer layer (ETL), an electron injection layer (EIL), etc. In example embodiments, a plurality of organic light emitting layers may be formed using light emitting materials for generating different colors of light such as a red color of light (R), a green color of light (G) and a blue color of light (B) in accordance with color pixels of the display device. Alternatively, the organic light emitting layer of the of the light emitting structure 342 may include a plurality of stacked light emitting materials for generating a red color of light, a green color of light, and a blue color of light to thereby emitting a white color of light.

The second electrode 345 may be disposed on the pixel defining layer 339 and the light emitting structure 342. The second electrode 345 may include a transparent material and/or a reflective material in accordance with the emission type of the display device. For example, the second electrode 345 may be formed using aluminum, alloy containing aluminum, aluminum nitride, silver, alloy containing silver, tungsten, tungsten nitride, copper, alloy containing copper, nickel, alloy containing nickel, chrome, chrome nitride, molybdenum, alloy containing molybdenum, titanium, titanium nitride, platinum, tantalum, tantalum nitride, neodymium, scandium, strontium ruthenium oxide, zinc oxide, indium tin oxide, tin oxide, indium oxide, gallium oxide, indium zinc oxide, etc. These may be used alone or in a combination thereof. In example embodiments, the second electrode 345 may also have a single layer structure or a multi layer structure, which may include a metal film, an alloy film, a metal nitride film, a conductive metal oxide film, and/or a transparent conductive film.

The second substrate 353 may be positioned on the second electrode 345. The second substrate 353 may include a transparent insulation substrate. For example, the second substrate 353 may include a glass substrate, a quartz substrate, a transparent resin substrate, etc. In example embodiments, a predetermined space may be provided between the second electrode 345 and the second substrate 353. This space may be filled with an air or an inactive gas such as a nitrogen (N₂) gas. Alternatively, a protection layer (not illustrated) may be additionally disposed between the second electrode 345 and the second substrate 353. For example, the protection layer may include a resin, for example, photoresist, acryl-based resin, polyimide-based resin, polyamide-based resin, siloxane-based resin, etc.

Although the display device includes the display panel such as an OLED panel of FIG. 3, the display device may include the display panel such as an LCD panel.

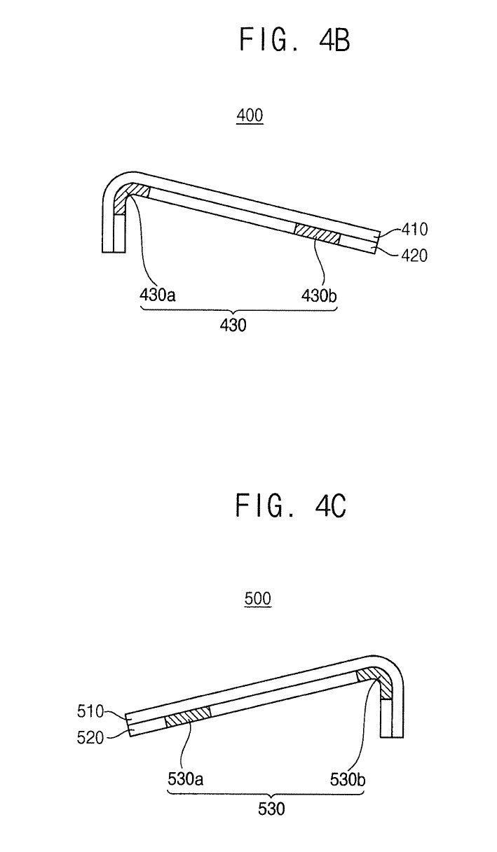

FIGS. 4A through 4C are diagrams illustrating changing shapes of a mobile device in accordance with example embodiments.

In example embodiments, an input value inputted by a user to a mobile device may include an outer curvature of a mobile device, a changing-pattern of the outer curvature of the mobile device, and/or a motion pattern of the mobile device. Although the outer curvature of the mobile device is described as the input value in FIGS. 4A through 4C, it should be understood that the input value may also be the changing-pattern of the outer curvature of the mobile device and/or the motion pattern of the mobile device.

Referring to FIG. 4A, the mobile device 300 may include a display panel 310, a supporting member 320, an electro active polymer 330, a driving controller, etc. In this case, the driving controller may control the electro active polymer 330 based on the input value.

The mobile device 300 may have a symmetric structure in which a left outer curvature is matched to a right outer curvature when a value of the left outer curvature is the same as a value of the right outer curvature, where the left outer curvature and the right outer curvature are inputted through the user application program. In addition, the mobile device 300 may operate a left electro active polymer pattern 330a and a right electro active polymer pattern 330b based on the value of the left outer curvature and the value of the right outer curvature, respectively. That is, the user may use the mobile device 300 having an optimized or improved shape structure according to surrounding circumstances of the user.

Referring to FIG. 4B, the mobile device 400 may include a display panel 410, a supporting member 420, an electro active polymer 430, a driving controller, etc. In this case, the driving controller may control the electro active polymer 430 based on the input value.

The mobile device 400 may have a non-symmetric structure in which a left outer curvature is not matched to a right outer curvature when a value of the left outer curvature is higher than a value of the right outer curvature, where the left outer curvature and the right outer curvature are inputted through the user application program. In addition, the mobile device 400 may operate a left electro active polymer pattern 430a and a right electro active polymer pattern 430b based on the value of the left outer curvature and the value of the right outer curvature, respectively. That is, the user may use the mobile device 400 having an optimized or improved shape structure according to surrounding circumstances of the user.

Referring to FIG. 4C, the mobile device 500 may include a display panel 510, a supporting member 520, an electro active polymer 530, a driving controller, etc. In this case, the driving controller may control the electro active polymer 530 based on the input value.

The mobile device 500 may have a non-symmetric structure in which a left outer curvature is not matched to a right outer curvature when a value of the left outer curvature is smaller than a value of the right outer curvature, where the left outer curvature and the right outer curvature are inputted through the user application program. In addition, the mobile device 500 may operate a left electro active polymer pattern 530a and a right electro active polymer pattern 530b based on the value of the left outer curvature and the value of the right outer curvature, respectively. That is, the user may use the mobile device 500 having an optimized or improved shape structure according to surrounding circumstances of the user.

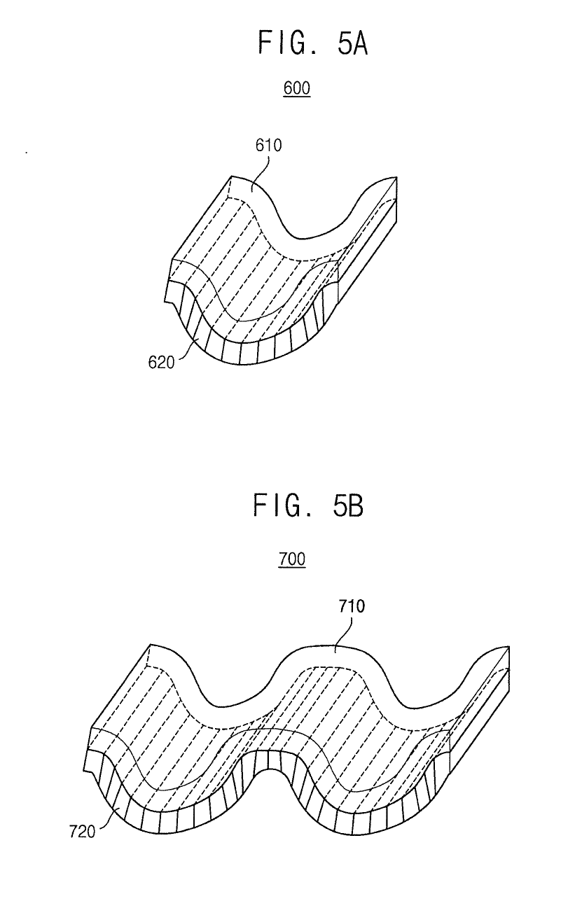

FIGS. 5A and 5B are diagrams illustrating changing a shape of a mobile device in accordance with example embodiments.

In example embodiments, an input value inputted by a user to a mobile device may include an outer curvature of a mobile device, a changing-pattern of the outer curvature of the mobile device, and/or a motion pattern of the mobile device. Although the motion pattern of the mobile device is described as the input value in FIGS. 5A and 5B, it should be understood that the input value may also be the outer curvature of the mobile device and/or the changing-pattern of the outer curvature of the mobile device.

Referring to FIG. 5A, the mobile device 600 may include a display panel 610, an electro active polymer 620, a driving controller, etc. In this case, the driving controller may detect an event of the mobile device 600 (e.g., a reception of a call, a reception of a text message, etc.).

A database may include a preset input signal corresponding to an event of the mobile device 600 when the driving controller detects the event of the mobile device 600. In one example embodiment, the preset input signal may be prestored in the database when the mobile device 600 is manufactured. In another example embodiment, the preset input signal may be stored or updated in the database by a user setting. In still another example embodiment, the preset input signal may be adaptively stored or updated in the database by reflecting a user's habit to use the mobile device 600. In this case, the driving controller may search the preset input signal, and may control the electro active polymer 620 based on the searched preset input signal.

For example, the driving controller may operate the electro active polymer 620 to have a single curvature structure when the event is a text message.

Referring to FIG. 5B, the mobile device 700 may include a display panel 710, an electro active polymer 720, a driving controller, etc. In this case, the driving controller may detect an event of the mobile device 700 (e.g., a reception of a call, a reception of a text message, etc.).

A database may include a preset input signal corresponding to an event of the mobile device 700 when the driving controller detects the event of the mobile device 700. In one example embodiment, the preset input signal may be prestored in the database when the mobile device 700 is manufactured. In another example embodiment, the preset input signal may be stored or updated in the database by a user setting. In still another example embodiment, the preset input signal may be adaptively stored or updated in the database by reflecting a user's habit to use the mobile device 700. In this case, the driving controller may search the preset input signal, and may control the electro active polymer 720 based on the searched preset input signal.

For example, the driving controller may operate the electro active polymer 720 to have a multi curvature structure when the event is a text message.

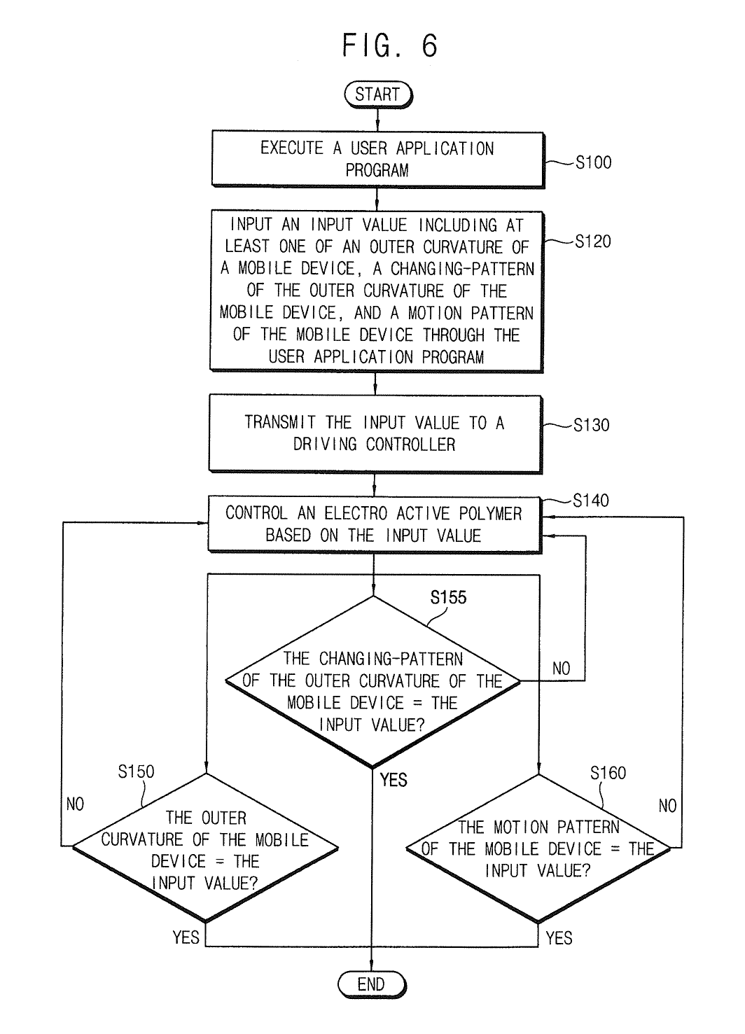

FIG. 6 is a flow chart illustrating a method of changing a shape of a mobile device in accordance with example embodiments.

Referring to FIG. 6, a user application program in a mobile device including a display panel, a supporting member, and an electro active polymer may be executed as shown in step S100.

Then, an input value including at least one of an outer curvature of the mobile device, a changing-pattern of the outer curvature of the mobile device, or a motion pattern of the mobile device may be inputted through the user application program (as shown in step S120.

Specifically, an input value may be provided or transmitted to the driving controller as shown in step S130.

Subsequently, the electro active polymer may be controlled based on the input value as shown in step S140.

In one example embodiment, a control of the electro active polymer may be stopped when the outer curvature of the mobile device is matched to the input value as shown in step S150. In another example embodiment, a control of the electro active polymer may be stopped when the changing-pattern of the outer curvature of the mobile device is matched to the input value as shown in step S155. In still another example embodiment, a control of the electro active polymer may be stopped when the motion pattern of the outer curvature of the mobile device is matched to the input value as shown in step S160.

In example embodiments, the shape of the mobile device (i.e., the outer curvature of the mobile device, the changing-pattern of the outer curvature of the mobile device, and the motion pattern of the mobile device) may be changed based on the driving signal generated by the input value according to surrounding circumstances of the user. As a result, portability and usability of the mobile device may be improved.

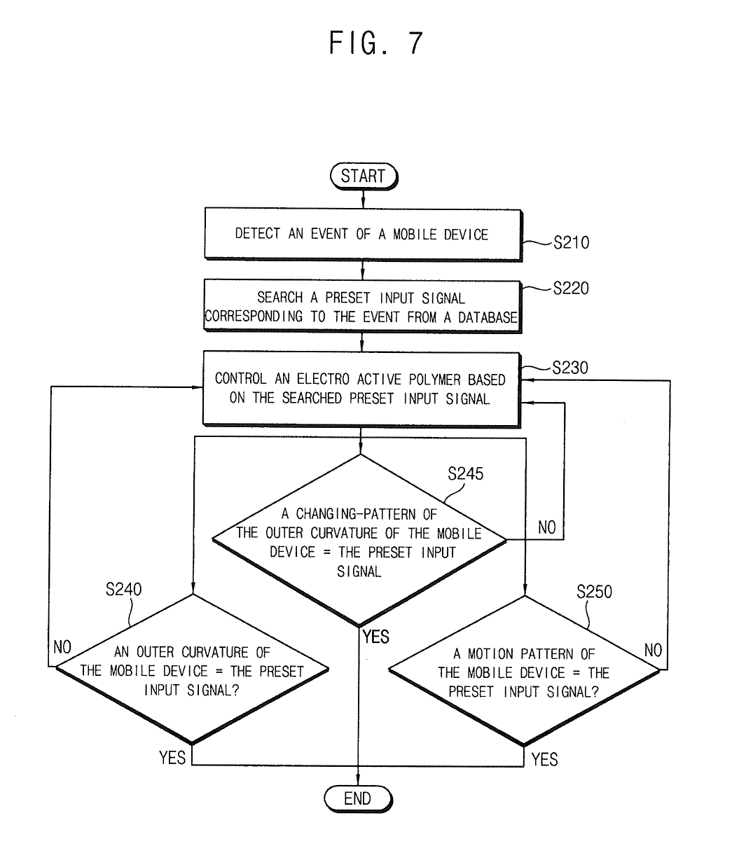

FIG. 7 is a flow chart illustrating a method of changing a shape of a mobile device in accordance with example embodiments.

Referring to FIG. 7, a driving controller may detect an event of a mobile device as shown in step S210.

In example embodiments, the event may include a reception of a call, a reception of a text message, etc. The preset input signal corresponding to the event may be stored in a database. In one example embodiment, the preset input signal may be prestored in the database when the mobile device is manufactured. In another example embodiment, the preset input signal may be stored or updated in the database by a user setting. In still another example embodiment, the preset input signal may be adaptively stored or updated in the database by reflecting a user's habit to use the mobile device.

The preset input signal corresponding to the event may be searched from the database as shown in step S220.

The electro active polymer may be controlled based on the searched preset input signal as shown in S230.

In example embodiments, the preset input signal may include at least one of an outer curvature of the mobile device, a changing-pattern of the outer curvature of the mobile device, or a motion pattern of the mobile device.

In one example embodiment, a control of the electro active polymer may be stopped when the outer curvature of the mobile device is matched to the preset input signal as shown in step S240. In another example embodiment, a control of the electro active polymer may be stopped when the changing-pattern of the outer curvature of the mobile device is matched to the preset input signal as shown in step S245. In still another example embodiment, a control of the electro active polymer may be stopped when the motion pattern of the outer curvature of the mobile device is matched to the preset input signal as shown in step S250.

A mobile device according to example embodiments may have an optimized or improved shape structure according to a user, a surrounding circumstance, and an input manner by including an electro active polymer of which a shape is changed based on an input value inputted by the user. As a result, portability and usability of the mobile device may be improved.

According to example embodiments of the invention, the mobile device may be an electronic device such as a mobile phone, a smart phone, a laptop computer, a tablet computer, a personal digital assistant (PDA), a portable multimedia player (PMP), a digital camera, a music player, a portable game console, a navigation device, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and aspects of the present inventive concept. Accordingly, all such modifications are intended to be included within the scope of the present inventive concept as defined in the claims, and their equivalents. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A mobile device comprising:
a flexible display panel;
a supporting member at a back side of the flexible display panel, the supporting member supporting the flexible display panel; and
an electro active polymer partially inserted in the supporting member, a shape of the electro active polymer being changed based on an input value inputted by a user.

2. The device of claim 1, further comprising:
a driving controller configured to control the electro active polymer based on the input value.

3. The device of claim 2, wherein the electro active polymer is a sheet-type and includes a left electro active polymer pattern and a right electro active polymer pattern that are independently controlled by the driving controller.

4. The device of claim 2, wherein the driving controller is configured to detect an event of the mobile device, and to control the electro active polymer based on the event.

5. The device of claim 4, wherein the driving controller includes a database that stores a preset input signal corresponding to the event, is configured to search the preset input signal from the database when the event is detected, and to control the electro active polymer based on the searched preset input signal.

6. The device of claim 5, wherein the preset input signal includes at least one of an outer curvature of the mobile device, a changing-pattern of the outer curvature of the mobile device, or a motion pattern of the mobile device, that is inputted through a user application program.

7. The device of claim 1, wherein the input value includes at least one of an outer curvature of the mobile device, a changing-pattern of the outer curvature of the mobile device or a motion pattern of the mobile device, that is inputted through a user application program.

8. A mobile device comprising:
a flexible display panel; and
an electro active polymer disposed on a back side of the flexible display panel, a shape of the electro active polymer being changed based on an input value inputted by a user.

9. The device of claim 8, further comprising:
a driving controller configured to control the electro active polymer based on the input value.

10. The device of claim 9, wherein the electro active polymer includes a plurality of electro active polymer patterns having a shell-shape, and supports the flexible display panel according to whether or not a voltage is applied to the electro active polymer.

11. The device of claim 9, wherein the driving controller is configured to detect an event of the mobile device, and to control the electro active polymer based on the event.

12. The device of claim 11, wherein the driving controller includes a database that stores a preset input signal corresponding to the event, is configured to search the preset input signal from the database when the event is detected, and to control the electro active polymer based on the searched preset input signal.

13. The device of claim 12, wherein the preset input signal includes at least one of an outer curvature of the mobile device, a changing-pattern of the outer curvature of the mobile device, or a motion pattern of the mobile device, that is inputted through a user application program.

14. The device of claim 9, wherein the input value includes at least one of an outer curvature of the mobile device, a changing-pattern of the outer curvature of the mobile device, or a motion pattern of the mobile device, that is inputted through a user application program.

15. A method of changing a shape of a mobile device, the method comprising:
executing a user application program;
inputting an input value including at least one of an outer curvature of a mobile device, a changing-pattern of the outer curvature of the mobile device, or a motion pattern of the mobile device through the user application program;
transmitting the input value to a driving controller; and
controlling an electro active polymer based on the input value.

16. The method of claim 15, further comprising:
detecting an event of the mobile device,
wherein the driving controller controls the electro active polymer based on the event.

17. The method of claim 15, wherein the driving controller includes a database that stores a preset input signal corresponding to the event, searches the preset input signal from the database when the event is detected, and controls the electro active polymer based on the searched preset input signal.

18. The method of claim 17, wherein the preset input signal includes the at least one of the outer curvature of the mobile device, the changing-pattern of the outer curvature of the mobile device, or the motion pattern of the mobile device, that is inputted through the user application program.

19. The method of claim 17, wherein controlling the electro active polymer is stopped when one or more of the outer curvature of the mobile device, the changing-pattern of the outer curvature of the mobile device, and the motion pattern of the mobile device are matched to the preset input signal.

20. The method of claim 15, wherein the input value includes the at least one of the outer curvature of the mobile device, the changing-pattern of the outer curvature of the mobile device, or the motion pattern of the mobile device, that is inputted through the user application program.

21. The method of claim 15, wherein controlling the electro active polymer is stopped when one or more of the outer curvature of the mobile device, the changing-pattern of the outer curvature of the mobile device, and the motion pattern of the mobile device are matched to the input value.
